(19) United States
(12) Patent Application Publication
(10) Pub. No.: US 2016/0027621 A1
(43) Pub. Date: Jan. 28, 2016

(54) PLASMA PROCESSING APPARATUS AND SAMPLE STAGE FABRICATING METHOD

(71) Applicant: Hitachi High-Technologies Corporation, Tokyo (JP)

(72) Inventors: Takumi TANDOU, Tokyo (JP); Akitaka MAKINO, Tokyo (JP); Hiromichi KAWASAKI, Tokyo (JP)

(73) Assignee: HITACHI HIGH-TECHNOLOGIES CORPORATION

(21) Appl. No.: 14/626,948

(22) Filed: Feb. 20, 2015

(30) Foreign Application Priority Data
Jul. 28, 2014 (JP) 2014-152486

(51) Int. Cl. H01J 37/32; H01L 21/683; H01L 21/67

(52) U.S. Cl. CPC H01J 37/32807; H01L 21/67069; H01L 21/6833; H01J 37/32697; H01J 37/32724; H01J 2237/334

(57) ABSTRACT

A plasma processing apparatus includes: a vacuum vessel, a processing chamber disposed inside of the vacuum vessel, inside of which plasma is formed, a sample stage disposed below the processing chamber, on whose upper surface a sample that is a target processed by using the plasma is mounted, a sintered plate of dielectric material constituting a mounting surface of the sample stage on which the sample is mounted, abase material of metal bonded to the sintered plate below it with a bonding layer made of an adhesive agent intervening therebetween, and a cooling medium flow channel disposed inside of the base material, through which a cooling medium flows, in which a shearing force of the bonding layer generated in a portion on the peripheral side of the sample stage is made smaller than that generated in a portion on the center side.

### BACKGROUND OF THE INVENTION

(1) Field of the Invention

The present invention relates to a plasma processing apparatus for processing a film structure disposed on an upper surface of a substrate-like sample, such as a semiconductor wafer, to form wiring in a fabrication process of a semiconductor device and, in particular, to a plasma processing apparatus for holding a sample on an upper surface of a sample stage disposed in a processing chamber inside of a vacuum vessel to process the sample by using plasma formed inside of the processing chamber.

(2) Description of the Related Art

Because of the trend of semiconductor device miniaturization, as the years rolled on, a processing accuracy has become tightened with which it is required to process a film structure disposed on an upper surface of a substrate-like sample, such as a semiconductor wafer, for example by etching to form wiring. It is important to appropriately manage a surface temperature of a wafer during etching in order to carry out the etching based on a pattern on a wafer surface with a high accuracy by using a plasma processing apparatus.

Recently, to meet the demand that a shape accuracy be further increased, there has been a need for the technology to rapidly and precisely adjust a wafer temperature correspondingly to each of a plurality of processing steps during processing of a wafer. To control a surface temperature of a wafer in a plasma processing apparatus inside of which the pressure is depressurized to a high degree of vacuum, conventionally, while a heat transfer medium (for example, cooling medium) composed of a fluid for adjusting temperature of a sample stage is forced to flow through a flow channel disposed inside of the sample stage, a heat transfer medium composed of a gas is introduced between an underside surface of the wafer and an upper surface of a sample on which the wafer is mounted, thereby increasing efficiency of transferring heat to the sample stage and adjusting temperature of the upper surface of the sample stage or the sample.

In a common configuration of such a sample stage, a member constituting a mounting surface of a circular wafer disposed on an upper surface of a cylindrical sample stage fulfills a function as an electrostatic chuck. In particular, the member has a function of sticking fast a wafer mounted on the upper surface of the sample stage to an upper surface of a film (sticking film) made of dielectric material constituting the mounting surface by using an electrostatic force to hold it, further a fluid for promoting heat transfer, such as an He gas, as a heat transfer medium is supplied between the surface of the mounting surface and the underside surface of the wafer as a heat medium, thereby increasing a heat transfer efficiency between the sample stage or a cooling medium flowing inside of the sample stage and the wafer in a vacuum vessel.

In such a configuration, the electrostatically sticking force by the electrostatic chuck of the sample stage has a direct effect on a heat transfer characteristic between the sample stage and a sample. In other words, a change in electrostatically sticking force of the sample stage causes temperature of the sample to change.

Well, if there is a change in surface shape having microscopic irregularities of a film made of dielectric material and constituting the electrostatic chuck of the sample stage, then an area of a contact surface between an underside surface of a sample, such as a semiconductor wafer, mounted on the film to be stuck fast thereto and the surface of the film changes, and also a distribution of many, minute regions constituting the contact surface changes, as a result, a performance of adjusting temperature of the sample changes. As a possible reason for causing such a change in surface shape of the sticking film, it is thought that the sticking film made of dielectric material is exposed to plasma formed inside of a processing chamber to remove extraneous matters adhered to a surface inside of the processing chamber, and its surface having irregularities described above is ground down and converted due to interaction with the plasma. That is, repetition of such a cleaning using plasma changes characteristics of electrostatically sticking a sample and a performance of adjusting temperature of the sample of the electrostatic chuck.

From such a background, as for a sticking system having a limited change in sticking force of the sticking film surface of the above electrostatic chuck, a Coulomb electrostatic chuck has been conventionally used. For example, as such a conventional technology, there is a known technology disclosed in JP-A-2004-349664 in which dielectric material is thermally sprayed to a surface of a cylindrical or disk-shaped substrate of aluminum to form a film, and the film is used to form a Coulomb electrostatic chuck.

This conventional technology discloses a configuration in which a film of dielectric material and a film-like electrode inside of the film, to which power is applied to stick fast a sample are formed by using thermal spraying, further dielectric material is thermally sprayed to an upper surface and also a side wall surface of a cylindrical substrate of aluminum providing a base material of a sample stage in order to coat and protect them In this conventional technology, to achieve a Coulomb sticking film, highly-pure alumina is used as dielectric material. The example intends to realize an electrostatic chuck that is cheap to fabricate and has a long useable life by using such a configuration.

On the other hand, even though ceramics as such alumina is used as material for a dielectric material film of an electrostatic chuck, then for example, when exposed to plasma that uses a fluorinated gas, the material may be ground down to produce foreign matters in a processing chamber. To solve a challenge of reducing an amount of produced foreign matters, a sintered body of dielectric material, instead of a film formed by thermal spraying, is considered to be adopted.

By using such a sintered body in which ceramic crystals are fired at a high temperature to densely combine with each other, it can be expected that an amount wasted by plasma is reduced and an amount of produced foreign matters is lowered. When, in this manner, as a dielectric material member of a surface of an electrostatic chuck, a sintered body of alumina ceramics is used, then generally, fabrication is carried out in the following process flow.

(1) An internal electrode for electrostatically sticking is patterned on a ceramic green sheet, for example by printing and coated with another green sheet, subsequently fired at a high temperature under a high pressure.

(2) Ceramics is polished until predetermined thickness and flatness are achieved. After surface polishing, the surface is, if necessary, shape-processed.

(3) An electrostatic chuck fabricated in a manner described above is bonded to and fixed on an upper surface of a disk, or of a cylindrical electrode block of metal constituting a base material of a sample stage with an adhesive agent intervening therebetween.

The above method provides a complete sample stage in which the sintered body having a function as an electrostatic chuck is bonded onto the electrode block. Note that a general electrode block has a flow channel disposed inside of it, through which a cooling medium flows to adjust temperature of the sample stage or the base material within a range of desired values.

As for such a configuration of a sample stage, for example, JP-B-4881319 (corresponding to U.S. Pat. No. 8,038,796) discloses an electrostatic chuck configured in the way that a heater and a metal or ceramic plate is provided on a seating, further on an upper stage thereof, a dielectric material layer is provided and each layer is bonded to each other by using an adhesive agent. This conventional technology discloses that, by controlling a variation in thickness of an adhesive agent in the in-plane direction in a sample mounting surface of a sample stage (that is, parallelism) to be not more than 0.0000254 m, a variation in heat conduction in a surface of a bonding layer is suppressed, thereby it can be attempted to uniformize temperature in a surface of the dielectric material layer.

### SUMMARY OF THE INVENTION

The above related art has a problem because the following points are not fully considered.

That is, in a configuration of a sample stage in which a sintered body having an internal electrode for an electrostatic chuck is bonded to an electrode block by using an adhesive agent, if the sintered body and the electrode block differ in constituting material, when temperature of the sample stage is controlled (raised or lowered), then the sintered body may peel off because of a difference in thermal expansion between the sintered body and the electrode block. Particularly, it is expected that in a future plasma processing apparatus, a diameter of a semiconductor wafer that is a sample is expanded (300 to 450 mm in diameter).

Therefore, with a change in dimension of a sample, it is required to expand a diameter of a sample stage and a range of adjustable temperature, and with such an enlargement of the dimension of a sample, it is expected that a sintered body constituting a mounting surface of a sample is more prone to peel off. That is, because the sintered plate bonded to an upper surface of a base material of the sample stage with a bonding layer intervening therebetween differs in rate of thermal expansion and characteristics from material constituting the base material or the bonding layer, a difference in distortion between the sample stage and the sintered plate becomes too enlarged if a processing temperature is comparably high, consequently cracks, losses and peeling may occur between the bonding layer and the base material or the sintered plate.

As just described, in the conventional technology, full consideration has not been paid regarding the fact that a sintered body or a bonding layer constituting a sample mounting surface of a sample stage peels off from the body of the sample stage, accordingly uniformity of a sample temperature is compromised and foreign matters are produced, thus causing a yield ratio of processing to be lowered.

An object of the present invention is to provide a plasma processing apparatus capable of boosting a yield ratio of processing.

The above object is achieved by a plasma processing apparatus including: a vacuum vessel, a processing chamber disposed inside of the vacuum vessel, inside of which plasma is formed, a sample stage disposed below the processing chamber, on whose upper surface a sample that is a target processed by using the plasma is mounted, a sintered plate of dielectric material constituting a mounting surface of the sample stage on which the sample is mounted, a base material of metal bonded to the sintered plate below it with a bonding layer made of an adhesive agent intervening therebetween, and a cooling medium flow channel disposed inside of the base material, through which a cooling medium flows, in which a shearing force of the bonding layer generated in a portion on the peripheral side of the sample stage is made smaller than that generated in a portion on the center side.

An adhesive agent bonded interface stress (hereinafter, referred as “stress”) caused by a difference in thermal expansion between the sintered body and the electrode block becomes maximum near the outermost periphery of the sample stage. Therefore, a thickness of the adhesive agent is thickened at a peripheral position, or a soft adhesive agent is used to relax the stress in the bonded interface. This allows a high thermal expansion material to be selectable for an electrode block (design limitation is dissolved), which allows us to be able to handle the increasing size of a sample stage and the expanding control range of temperature needed in the next generation.

Note that because a thickness of an adhesive agent also has an effect on heat-transmission characteristics of an electrode block and a sintered body, a configuration is provided in which an adhesive agent is applied thinly in a wide area in a surface of a sample stage to secure a high heat conduction and the thickness of the adhesive agent is thickened only in a peripheral portion subject to an increased stress.

Other objects, features and advantages of the invention will become apparent from the following description of the embodiments of the invention taken in conjunction with the accompanying drawings.

### BRIEF DESCRIPTION OF THE DRAWINGS

FIG. 1 is a longitudinal cross-sectional view for showing schematically a configuration of a plasma processing apparatus according to an example of the present invention;

FIG. 2 is an enlarged, longitudinal cross-sectional view for showing schematically a configuration of a sample stage in the example shown in FIG. 1;

FIGS. 3A and 3B are views for showing a second example of a bonding layer of a sample stage according to the present invention;

FIGS. 4A and 4B are graphs for showing schematically the relation between a shape of a bonding layer and a stress generated inside of the bonding layer;

FIGS. 5A and 5B are longitudinal cross-sectional views for showing schematically a configuration of a sample stage according to a modification of the example shown in FIG. 1;

FIG. 6 is a longitudinal cross-sectional view for showing schematically a configuration of a sample stage according to another modification of the example shown in FIG. 1; and

FIG. 7 is a longitudinal cross-sectional view for showing schematically a configuration of a sample stage according to still another modification of the example shown in FIG. 1.

### DETAILED DESCRIPTION OF THE INVENTION

Now, an example of the present invention will be described below with reference to the drawings.

### Example 1

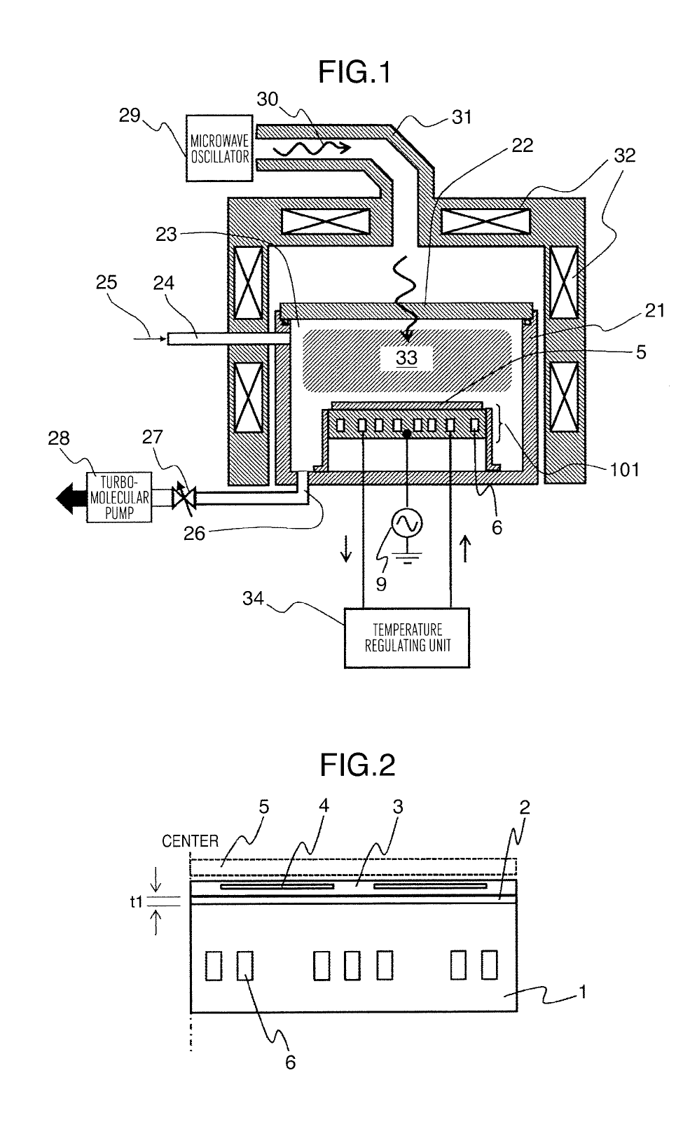

A first example of the present invention will be described using FIGS. 1 to 5B. FIG. 1 is a longitudinal cross-sectional view for showing schematically a configuration of a plasma processing apparatus according to an example of the present invention. Particularly, FIG. 1 shows an apparatus in which an electric field of a microwave and a magnetic field interacting with the electric field are provided to form plasma in a processing chamber inside of a vacuum vessel and Electron Cyclotron Resonance (ECR) is used to etch a film structure of an upper surface of a sample, such as a semiconductor wafer.

A plasma processing apparatus of this example includes, roughly divided, a vacuum vessel 21 having a processing chamber 23 inside of which plasma is formed, a plasma forming section that is disposed above the vacuum vessel 21 and forms an electric field or a magnetic field to form plasma in the processing chamber 23 and an exhaust section that is disposed below the vacuum vessel 21 and has a vacuum pump, such as a turbo-molecular pump, in communication with the processing chamber 23 to evacuate and depressurize an inside space. The processing chamber 23 is a cylindrical space and the vacuum vessel 21 disposed to surround the periphery of the processing chamber 23 has a cylindrical portion of metal.

Above a cylindrical side wall of the vacuum vessel 21, a window member 22 is disposed, the window member 22 mounted on a top edge of the side wall, having a disk shape and made of quartz that allows the electric field of a microwave to penetrate through the inside thereof. Between the top edge of the side wall and a lower surface of a peripheral edge of the window member 22, a seal member, such as an O-ring, is placed and held to provide airtight sealing between the inside of the processing chamber 23 and the outside set at atmospheric pressure, and the window member 22 forms the vacuum vessel 21. Also, inside of the processing chamber 23 below it, a cylindrical sample stage 101 is provided, and above an upper surface of the sample stage, a circular mounting surface is provided, and on the mounting surface, a substrate-like sample 5, such as a semiconductor wafer having a disk shape, is mounted.

With the top portion of the side wall of the vacuum vessel 21, a gas introduction pipe 24 is coupled, and process gas 25 flowing through the gas introduction pipe 24 passes through a gas introduction hole disposed below the window member 22 and is introduced into the processing chamber 23. The process gas 25 introduced into the processing chamber 23 is excited by the interaction of the electric field and the magnetic field provided in the processing chamber 23 to form plasma 33.

On the lower portion of the processing chamber 23 below the sample stage 101, an exhaust port 26 is disposed to communicate the exhaust section with the inside of the processing chamber 23. The process gas 25 introduced into the processing chamber 23, the plasma and particles, such as reaction products produced during processing of the sample 5, in the processing chamber 23 are exhausted through the exhaust port 26 by operation of the exhaust section.

Below the exhaust port 26, a turbo-molecular pump 28, i.e. a kind of vacuum pump, is disposed with a pressure regulating valve 27 intervening therebetween. A pressure inside of the processing chamber 23 is adjusted to a suitable pressure for processing (in this example, to the degree of several Pas) by balancing an amount of exhaust and a volume of flow of the process gas 25 entering from the gas introduction hole, the amount of exhaust determined by adjusting an aperture of the pressure regulating valve 27 that rotates around a shaft extending horizontally and traversing the exhaust port 26 or a flow channel for communicating the exhaust port 26 with an inlet port of the turbo-molecular pump 28 to increase and decrease a cross-section area of the flow channel.

The plasma forming section above the processing chamber 23 of the vacuum vessel 21 includes a waveguide 31 through which an electric field of a microwave propagates and a microwave oscillator 29 that is disposed on an end of the waveguide 31 and oscillates to form the electric field of a microwave in the waveguide 31. Also, the other end of the waveguide 31 is coupled with the top portion of a cylindrical space disposed above the window member 22.

The electric field 30 of a microwave generated by the microwave oscillator 29 passes through the waveguide 31 and is introduced into the cylindrical space from above it, and in the electric field 30 of a microwave, a particular mode thereof resonates to be augmented inside of the space. The electric field 30 of a microwave in such a state is introduced into the processing chamber 23 from above it through the window member 22.

Also, above the processing chamber 23 of the vacuum vessel 21 and around the processing chamber 23 and the waveguide 31 in the horizontal direction, a plurality of solenoidal coils 32 are disposed to surround the processing chamber 23, and a magnetic field formed by applying a direct current to the coils is provided in the processing chamber 23. The magnetic field is adjusted to a density or strength suitable for a frequency of the electric field 30 of a microwave to form ECR.

In this example, to control temperature of the sample 5 that is a semiconductor wafer, the cooling medium is made to flow through a cooling medium flow channel 6 disposed inside of the sample stage 101, thus conducting heat-exchange between the cooling medium and the sample stage, then the sample 5. With the cooling medium flow channel 6, a temperature regulating unit 34 is coupled through a duct line through which the cooling medium flows, and the cooling medium whose temperature is adjusted within a range of predetermined values in the temperature regulating unit 34, such as a chiller, passes through the duct line and enters into a cooling medium flow channel 6 to conduct heat-exchange while passing through it, subsequently the cooling medium is exhausted and returns to the temperature regulating unit through the duct line, thus forming a pathway through which the cooling medium circulates.

Also, in the sample stage 101, a cylindrical or disk-shaped base material of metal not shown is disposed, and the base material has the above cooling medium flow channel 6 therein and is electrically connected to a high-frequency (radio frequency) power source 9 to supply a high-frequency power. Furthermore, an upper surface of the sample stage 101 constitutes a circular, flat plane on which the sample 5 is mounted and has a depressed portion where a cover is disposed to surround around the periphery of the circular, upper surface and to protect the sample stage 101 against the plasma 33.

With the side wall of the vacuum vessel 21 of the plasma processing apparatus formed as described above, another vacuum vessel not shown is coupled, and a conveying space disposed inside of the another vacuum vessel, which is a vacuum conveying vessel inside of which a conveying robot is disposed, is communicated with the processing chamber 23 in the vacuum vessel 21 by a gate providing a pathway through which the sample 5 is conveyed and passes. The sample 5 prior to processing is brought from the vacuum conveying vessel into the processing chamber 23, delivered to the sample stage 101 and mounted on the upper surface of the mounting surface in the state where the sample 5 is held on a slide arm of the robot in the vacuum conveying vessel and a gate valve not shown is opened, the gate valve releasing or air tightly sealing the communication of the gate between the vacuum vessel 21 and the vacuum conveying vessel.

The sample 5 mounted on the mounting surface in contact with it is electrostatically stuck fast to the mounting surface by an electrostatic force of charges formed in a dielectric material member constituting the mounting surface by supplying power to an electrostatic chuck not shown. In such a state, a gas for heat transfer, such as He, is supplied between an underside surface of the sample 5 and the mounting surface, accordingly promoting heat transfer between the sample 5 and the dielectric material of the mounting surface, then the sample stage 101.

The process gas 25 is supplied from the gas introduction hole into the processing chamber 23 from above it, and by operation of the turbo-molecular pump 28 and the pressure regulating valve 27, a gas or particles in the processing chamber 23 are exhausted through the exhaust port 26 outside of the processing chamber 23. By balancing an amount of process gas 25 introduced and a volume of exhaust (exhaust flow rate) of the particles through the exhaust port 26, an internal pressure of the processing chamber 23 is adjusted to within a range of desired values.

In this state, the electric field of a microwave and the magnetic field generated by the solenoidal coils 32 are provided through the waveguide 31 and the window member 22 in the processing chamber 23, and ECR formed by the interaction between the electric field 30 of a microwave and the magnetic field from the solenoidal coils 32 is used to excite particles of the process gas 25, thereby producing the plasma 33 in the processing chamber 23. A film, which is a processing target disposed on the upper surface of the sample 5 and held on the mounting surface of the sample stage 101, is etched by the interaction between charged particles and excited active particles in the plasma 33. In this example, by providing the circulating pathway through which the cooling medium whose temperature is adjusted during processing circulates and is supplied in the sample stage 101, the temperature of the sample stage 101, then the sample 5 is adjusted to within a range of values suitable for processing.

When a detector, not shown, to determine completion of processing detects the completion of processing, the operation of providing the electric field and the magnetic field is stopped, the plasma 33 is extinguished and the gate valve is opened, and the arm of the conveying robot extends into the processing chamber 23 to take the sample 5 at a position in the sample stage 101 and to receive it on the arm, subsequently the arm contracts to carry the sample 5 outside of the processing chamber 23, subsequently another sample 5 prior to processing is brought into the processing chamber 23.

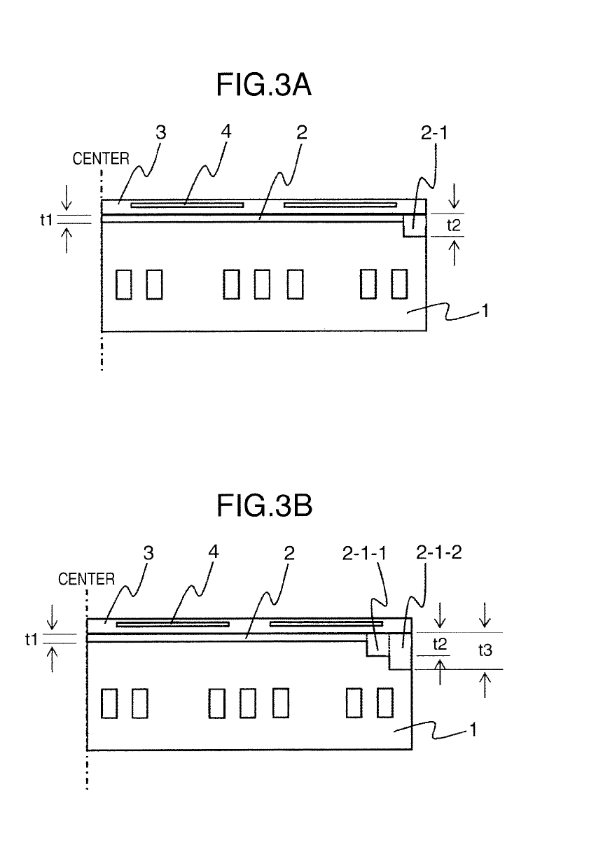

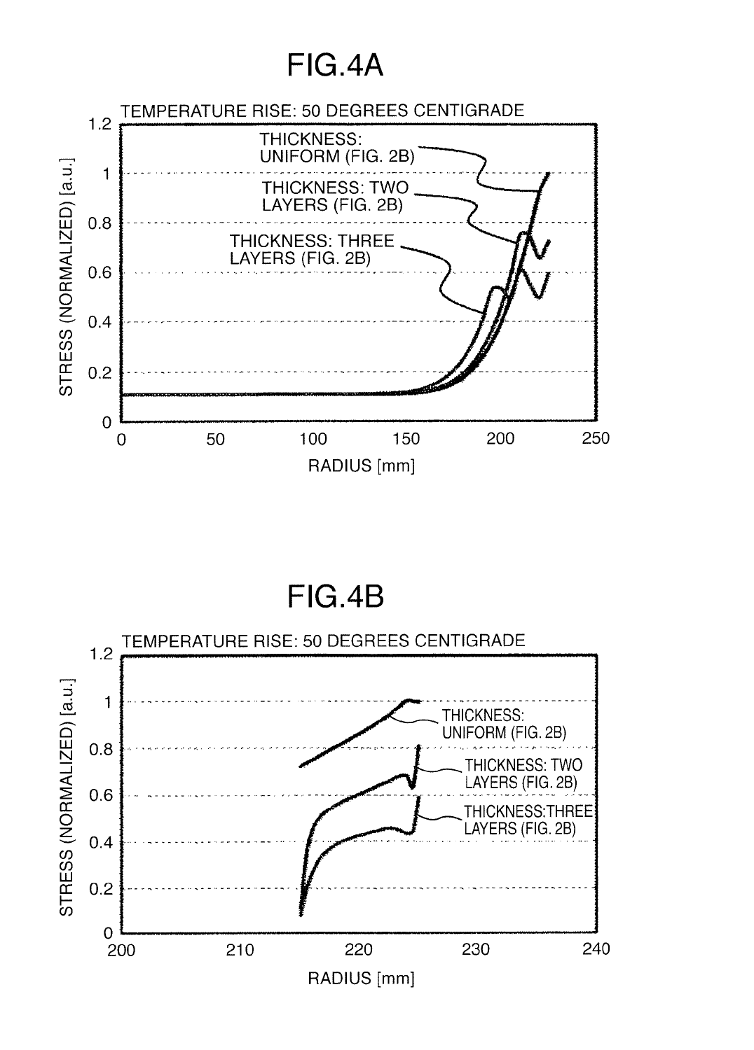

Next, a detailed configuration of the sample stage 101 according to this example will be described using FIG. 2. FIG. 2 is an enlarged, longitudinal cross-sectional view for showing schematically a configuration of the sample stage in the example shown in FIG. 1.

In this example, the sample stage 101 includes a disk-shaped sintered plate 3 having an electrostatically sticking function, the sintered plate being, with a bonding layer 2 intervening, disposed above an upper surface of an electrode block 1 that is a cylindrical member of metal and has a built-in cooling medium flow channel 6, i.e. a pathway through which a heat exchange medium (hereinafter, referred as “cooling medium”). Inside of the sintered plate 3, an internal electrode 4 is disposed, and a direct voltage is applied to the internal electrode 4 to form a desired polarity, thereby accumulating charges on the inner side of an upper surface of the sintered plate 3 to generate static electricity, accordingly the sample 5 mounted over the upper surface is stuck fast to the upper surface of the sintered plate 3 and held.

The sintered plate 3 is a dielectric material member made by forming a single or a plurality of ceramic materials, such as alumina and yttria, to a predetermined disk shape and firing it. The sintered plate 3 having the internal electrode 4 disposed therein may be made by firing an unfired member of the above ceramic material that is formed to a disk shape and preliminarily capsulates an electrode, or may be formed by placing a film-like electrode between another sintered plates having the same diameter and placing it between these sintered plate members to be joined to each other.

As stated above, in the example, during processing, or before or after processing, a cooling medium whose temperature is adjusted to within a range of predetermined values by the temperature regulating unit 34 is supplied to the cooling medium flow channel 6 inside of the electrode block 1 and circulates, accordingly the electrode block 1, then the sample 5 is adjusted to have a desired temperature suitable for processing. In the state that the plasma 33 is formed, the upper surface of the sample 5 is exposed to the plasma 33 and receives heat from the plasma so that the temperature of the sample 5 rises and the heat of the sample 5 is transferred to the sintered plate 3 constituting the mounting surface for the sample 5. Furthermore, the heat is transferred to the electrode block 1 of metal through the sintered plate 3 and the cooling medium flowing through the cooling medium flow channel 6 heat-exchanges with the electrode block 1. As a result, the cooling medium and the sample 5 heat-exchanges with each other.

In such a manner, the heat transferred from the plasma 33 to the sample 5 is transferred to the sintered plate 3 and the electrode block 1. When the electrode block 1 and the sintered plate 3 have a different material, for example, the electrode block 1 is made of metal and the sintered plate 3 is made of alumina ceramics, the members greatly differ in expansion because of a different linear expansion coefficient of material constituting each member, and from the difference in amount of expansion, a shearing force acts on a surface of each member, particularly on a surface of a portion to which other member is joined or connected.

That is, if the temperature of the cooling medium supplied to the cooling medium flow channel 6 is raised or lowered, then the electrode block 1 and the sintered plate 3 differ in generated amount of thermal expansion or of thermal contraction of the electrode block 1 and the sintered plate 3, and schematically, a stress to shear the bonding layer 2 is generated inside of the bonding layer 2 that is placed between them and joins them to each other. As a result, if the generated stress exceeds strength of an adhesive force between the surface of the bonding layer 2 and the surface of the electrode block 1 or the sintered plate 3, then peeling occurs between them.

An etching apparatus in the next generation demands the expanding diameter of a wafer (300 to 450 mm in diameter) and the expanding control range of wafer temperature in etching. When a dimension of the sample 5 mounted on the sintered plate 3 becomes larger and an outer diameter of the electrode block 1 and the sintered plate 3 becomes expanded, and when a range to adjust temperature of the sample stage 101 becomes expanded, then because of the above difference in amount of expansion, the stress generated in the bonding layer 2 becomes greater.

On the other hand, because a required performance of heat transfer between the sample 5 and the cooling medium flow channel 6 or the electrode block 1 remains at a conventional level or becomes higher, it is expected that a thickness t 1 of the bonding layer 2 is required to be thinner. This will increase a generated shearing force in the conventional configuration and it is shown that it is necessary to devise a configuration capable of suppressing, against such a force, peeling between the bonding layer 2 and two members between which the bonding layer intervenes.

FIGS. 3A and 3B are longitudinal, cross-sectional views for showing schematically a configuration of a bonding layer of the sample stage 101 of the example shown in FIG. 2. FIG. 3A shows a configuration in which a peripheral bonding layer 2-1 having a thickened thickness is disposed in a peripheral edge portion of the bonding layer 2.

The above stress generated in the bonding layer 2 caused by the shearing force due to the difference in linear expansion coefficient between the electrode block 1 and the sintered plate 3 becomes maximum in the outermost peripheral edge portion if the thickness t1 of the bonding layer 2 has a uniform value or has an approximated value viewed to be uniform to a similar degree in a portion on the center side. Then, in the example, a peripheral bonding layer 2-1 having a thickness thicker than the thickness t1 in the portion on the center side is disposed in the peripheral edge portion of the bonding layer 2 so that the stress generated in the peripheral bonding layer 2-1 is reduced.

In FIG. 3A, in the peripheral bonding layer 2-1, the bonding layer 2 is disposed above a ring-shaped depressed portion that is separated by a step and disposed on the upper surface of the electrode block 1 so that its deepness become large from the center toward the periphery of the cylindrical electrode block 1, and above the bonding layer 2, the sintered plate 3 with a thickness having a uniform value or an approximated value viewed to be uniform to a similar degree is mounted and joined to the bonding layer 2 so that the thickness is made larger than that in a region on the center side of the upper surface of the electrode block 1. Furthermore, FIG. 3B shows an example in which the peripheral bonding layer 2-1 includes two regions formed by further separating the depressed portion by another step.

Because the stress generated inside of the bonding layer 2 becomes larger toward near the peripheral edge of the electrode block 1 or the sintered plate 3, in FIG. 3B, a thickness t3 of a peripheral bonding layer 2-1-2 situated on the outermost peripheral side is made thicker than a thickness t2 of a peripheral bonding layer 2-1-1 on the center side that is separated by a step, thereby further reducing the stress inside of the peripheral bonding layer 2-1. This example shows an example in which in a region, which is separated by a step, of a ring-shaped depressed portion disposed centrically to a portion on the center side, two peripheral bonding layers are multiply-disposed in the radial direction of the electrode block 1, and the peripheral bonding layer 2-1 is divided into two sections, but the invention is not limited to this, and the peripheral bonding layer 2-1 may include more steps and more depressed portions.

FIGS. 4A and 4B are graphs for showing schematically the relation between a shape of a bonding layer and a stress generated inside of the bonding layer. In the lateral axis, a radial position is shown and in the vertical axis, a normalized stress inside of the bonding layer is shown, FIG. 4A shows a stress generated near a bonded interface above the bonding layer and FIG. 4B shows a stress generated near the bonded interface below the bonding layer.

Here, the situation is shown where material of the electrode block 1 is Al (A5052) having a thickness of 50 mm, material of the bonding layer 2 is an epoxy adhesive agent having a thickness of 0.5 mm, and the sintered plate 3 is alumina ceramics having a thickness of 2 mm. Also, an outer diameter of the sample stage 101 was 450 mm. Assuming that temperature of the sample stage 101 changes uniformly as a whole, and at the room temperature of 20 degrees centigrade, a stress generated in the bonding layer is zero, then a calculated value of the stress that corresponds to a change in radial position from the center of the electrode block 1 is shown in the graph in the situation where the temperature of the electrode block 1 rises to 70 degrees centigrade (amount of increased temperature is 50 degrees centigrade).

According to the drawings, it is seen that the stress generated inside of the bonding layer 2, as described above, increases toward the peripheral edge of the electrode block 1 or the sintered plate 3. Also, if the peripheral bonding layer 2-1 is provided in the portion on the peripheral side of the bonding layer 2, then it is seen that the stress generated in the peripheral portion is reduced.

As for dimensions of the peripheral bonding layer 2-1 in the drawings, in FIG. 3A, the peripheral bonding layer 2-1 has R=215 to 225 mm, the thickness t2=1 mm, and in FIG. 3B, the peripheral bonding layer 2-1-1 has R=200 to 215 mm, the thickness t2=1 mm, and the peripheral bonding layer 2-1-2 has R=215 to 225 mm, the thickness t3=2 mm. Also, a corner portion of the step that separates the depressed portion of the upper surface of the electrode block 1 has an R-shape in the cross-section so that the stress does not concentrate on the corner portion. Note that to prevent the stress from concentrating, the step portion may be tapered.

As described above, in this example, the peripheral bonding layer 2-1 having the thickness set to be thicker is disposed in the peripheral edge portion of the bonding layer 2, thus reducing the stress in the peripheral bonding layer. On the other hand, in the situation where in the peripheral bonding layer 2-1, the thickness of the bonding layer 2 is increased, it is a matter of concern that in the peripheral edge portion of the bonding layer 2, a performance of heat transmission between the electrode block 1 and the sintered plate 3 (thermal transmittance or thermal transmissibility) is lowered. Against such a problem, at least one circuit of the multiple cooling medium flow channels 6 disposed concentrically in the electrode block 1 may be disposed to situate immediately below the depressed portion of the peripheral portion of the upper surface of the electrode block 1 corresponding to the peripheral bonding layer 2-1.

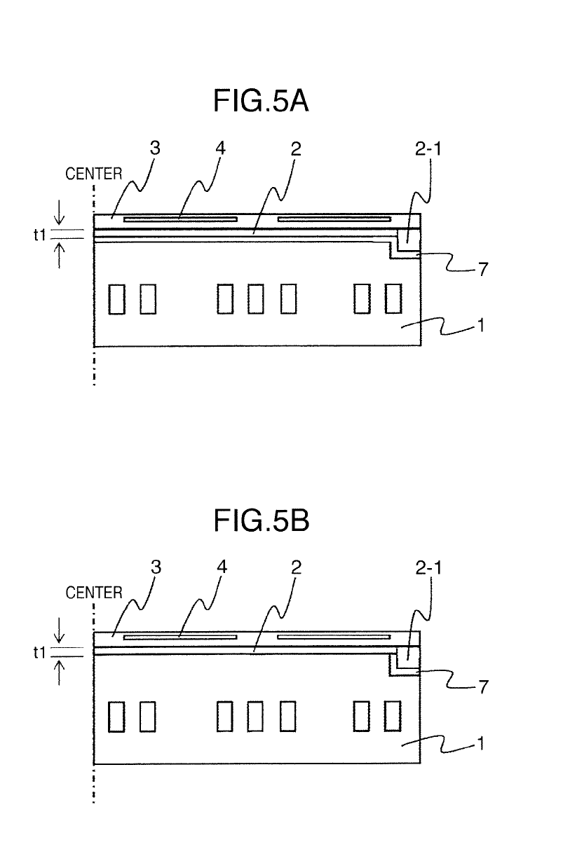

FIGS. 5A and 5B are longitudinal, cross-sectional views for showing schematically a configuration of a sample stage according to a modification of the example shown in FIG. 1. FIG. 5A shows a configuration in which a bonding auxiliary layer 7 is placed between the bonding layer 2 and the mounting surface of the electrode block 1 to which the sintered plate 3 is bonded with the bonding layer 2 intervening therebetween.

Generally, an adhesive agent changes in adhesive force correspondingly to a bonding target. For example, a particular adhesive agent has a high adhesive force to the sintered plate 3 of alumina ceramics, but a low adhesive force to the electrode block 1 of aluminum. In such a condition, to raise the adhesive force, in this example, the bonding auxiliary layer 7 that is a film layer made from the same material as the sintered plate 3 was placed between the bonding layer 2 and the mounting surface of the electrode block 1.

That is, in the situation where the sintered plate 3 is of alumina, a film or layer is preliminarily formed of alumina in the surface of the electrode block 1, subsequently the film, on which the sintered plate 3 is mounted, is bonded to the electrode block 1 with the bonding layer 2 intervening therebetween. Providing such a bonding auxiliary layer 7 allows the bonding layer 2 to exert a high adhesive force on both of the upper surface and the lower surface.

Such a bonding auxiliary layer 7 can be achieved by applying a conventional technology, for example, by thermally spraying alumina particles in a semi-molten state at a high temperature or by anodizing the upper surface of the electrode block 1. Note that it is thought that the bonding auxiliary layer 7 also contributes to blocking heat transmission between the electrode block 1 and the sintered plate 3. Then, as shown in FIG. 5B, the bonding auxiliary layer 7 may be disposed only below the peripheral bonding layer 2-1 having an increased value of the stress, and the bonding auxiliary layer 7 does not intervene in the portion on the center side so that the upper surface of the electrode block 1 contacts with the bonding layer 2.

In the above modification, the bonding auxiliary layer 7 is placed between the upper surface of the electrode block 1 and the bonding layer 2, but the bonding auxiliary layer 7 made from the same material as the electrode block 1 may be placed between the sintered plate 3 and the bonding layer 2.

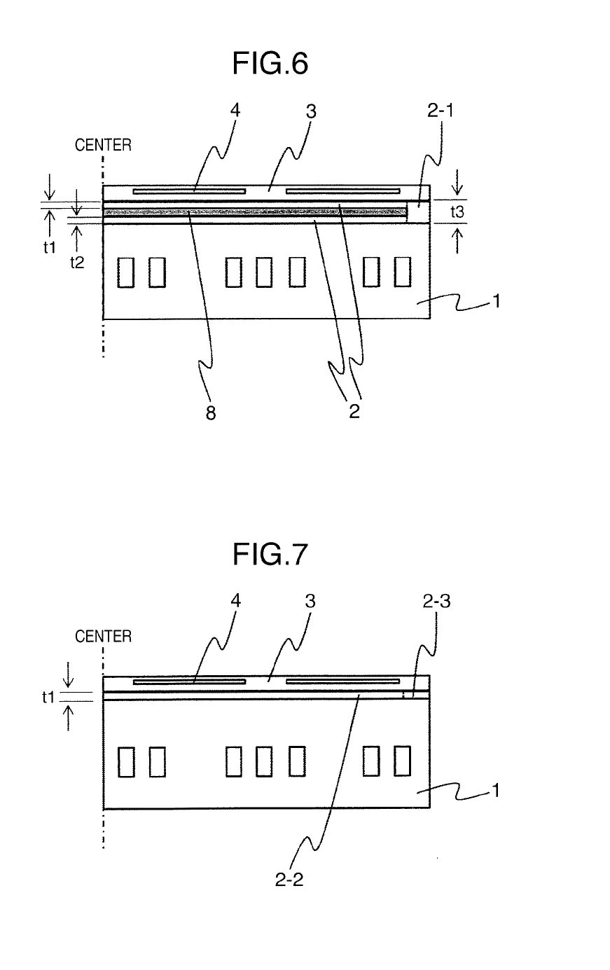

Another modification of the above example will be described using FIG. 6. FIG. 6 is a longitudinal, cross-sectional views for showing schematically a configuration of a sample stage according to another modification of the example shown in FIG. 1.

Also in this example, the sintered plate 3 having an electrostatically sticking function is disposed above the upper surface of the electrode block 1 and bonded to the electrode block 1 with the bonding layer 2 intervening therebetween. Furthermore in this example, a plurality of heater layers 8 that are metal films are disposed inside of the bonding layer 2. The heater layers 8 of this example are disposed in a portion of a region where the electrostatically sticking, internal electrodes 4 disposed inside of the sintered plate 3 is disposed, or in the region internally-including the whole.

Due to such a disposition of the heater layer 8, a non-uniform distribution of temperature is improved in the in-plane direction of the mounting surface, thus allowing distribution of temperature in the sample 5 to approach a more uniform distribution. Alternatively, a shift from a desired temperature distribution is reduced and the result of processing is made to approach a desired shape so that a yield ratio of processing is improved.

Also in the example, in the bonding layer 2, let a thickness of the top portion that is a portion between the sintered plate 3 and the heater layer 8 be ti, a thickness of a lower portion between the heater layer 8 and the electrode block 1 be t2, further, similarly to FIG. 1, a thickness of the peripheral bonding layer 2-1 disposed at a position corresponding to the peripheral edge portion of the upper surface of the sintered plate 3 or the electrode block 1 be t3.

The thickness t3 of the bonding layer 2 having the heater layer 8 satisfies the relation t3>(t1+t2). Also, the peripheral edge of the heater layer 8 on the outermost peripheral side is placed inside of the peripheral edge of the upper surface of the sintered plate 3 or the electrode block 1, accordingly the peripheral bonding layer 2-1 is disposed in the peripheral edge portion of the bonding layer 2.

Also, instead of the heater layer 8, a metal plate may be disposed to disperse heat in the in-plane direction of the mounting surface or the upper surface of the electrode block 1 Note that also in the configuration of this modification, similarly to FIG. 5, the bonding auxiliary layer 7 made from the same material as the upper or lower member may be placed between the bonding layer 2 and the upper or lower member.

Next, another modification of the above example will be described using FIG. 7. FIG. 7 is a longitudinal, cross-sectional views for showing schematically a configuration of a sample stage according to another modification of the example shown in FIG. 1.

Also in this example, similarly to the example shown in FIG. 1, the sintered plate 3 internally-including the electrostatically sticking, internal electrode 4 above the upper surface of the electrode block 1 is bonded to the electrode block i with the bonding layer 2 intervening therebetween and disposed. In the example, the used material of the bonding layer 2 varies correspondingly to a position in the radial direction of the sintered plate 3 or the electrode block 1, and in a region on the center side, a hard bonding layer 2-2 that uses a hard adhesive agent having a high hardness is disposed, and in a region on the peripheral side, a soft bonding layer 2-3 that uses a soft adhesive agent having a low hardness is disposed.

As stated above, because the stress generated in the bonding layer 2 in the peripheral edge portion becomes higher than that on the center side, a softer adhesive agent is used in the region on the peripheral side and an acceptable amount of deformation of the bonding layer 2 is made large in the region on the peripheral side so that the stress due to the shearing force in the bonding layer 2 is reduced. Note that definition of hardness and softness may be specified as a Young's modulus of the bonding layer 2 when the adhesive agent is cured. In this situation, the adhesive agent is selected in the region on the peripheral side to have a Young's modulus lower than in the region on the center side and used to form the bonding layer 2.

A schematic process flow for fabricating the sample stage 101 according to the modification by using an adhesive agent that differs in material between the inside region and the outside region of the bonding layer 2 for bonding the electrode block 1 and the sintered plate 3 to each other is as follows.

(1) An adhesive agent is applied to an upper surface of the electrode block 1, the upper surface to which the sintered plate 3 is bonded, and on the upper surface, the sintered plate 3 is mounted. In this example, a thermosetting, adhesive agent is used.

(2) Subsequently, a load is applied to the electrode block 1 or the sintered plate 3 in the direction to catch them (vertically in FIG. 7) until the bonding layer 2 reaches a desired thickness. In such a manner, an excess, adhesive agent is pushed out of a surface to the peripheral side, the surface being a bonding target portion of the electrode block 1 or the sintered plate 3.

(3) The electrode block 1 or the sample stage 101 is heated as a whole to thermally cure the adhesive agent.

(4) The adhesive agent cured in the state of being pushed out of the bonding target surface to the periphery in the process (2) is removed by a conventionally known method

If as the adhesive agent for forming the bonding layer 2, an adhesive agent different in material or quality of material is used in the region on the center side and in the region on the peripheral side, then, in the process (2), because a distance between the sintered plate 3 and the electrode block 1 becomes shortened, a trouble may occur, for example, the adhesive agent in the region on the center side is pushed out to flow into the region on the peripheral side, accordingly the adhesive agent changes in quality, and the soft adhesive agent 2-3 is completely pushed out in the region on the peripheral side, accordingly the bonding layer 2 is occupied to the peripheral edge portion by the hard adhesive agent 2-2. Also, for example, if a thermosetting, adhesive agent is used in the region on the center side and a room-temperature curing, adhesive agent is used in the region on the peripheral side, then during pushing the sintered plate 3 and the electrode block 1 against each other to achieve a desired thickness of the bonding layer 2 in the process (2), the adhesive agent in the region on the peripheral side begins to cure, as a result, it is also thought that it is difficult to manage the thickness of the bonding layer 2 with a good accuracy.

To avoid such a problem, first, the processes (1), (2), (3) are carried out in the state where only the adhesive agent for the region on the center side is applied. Subsequently, a space of the region on the peripheral side of the electrode block 1 and the sintered plate 3 between them is cleaned so that the adhesive agent is removed, the adhesive agent pushed out of the region on the center side to the region on the peripheral side where the soft bonding layer 2-3 is essentially to be disposed.

Next, after cleaning the region on the peripheral side, into the region, the adhesive agent having a low hardness for the peripheral side may be introduced to fill it and the adhesive agent in the region on the peripheral side may be cured. Furthermore, the whole of the bonding layer is raised in temperature to cure the adhesive agent in the region on the center side, thus forming the whole of the bonding layer 2 of the cured adhesive agent.

Note that to be able to improve the work efficiency when in the region on the peripheral side, cleaning the hard adhesive agent and introducing the soft adhesive agent are carried out as described above, or to narrow a gap between the adhesive agents, a gap between the electrode block 1 and the sintered plate 3 may be made large in the region on the peripheral side of the bonding layer 2. That is, in the configurations shown in FIG. 3A, 3B and 5A, 5B, as the peripheral bonding layer 2-1 disposed in the depressed portion of the peripheral edge portion, the soft adhesive agent may be provided.

Note that it is expected that the adhesive agent in the peripheral region is exposed to radicals (chemically active species), ultraviolet light and the like generated during plasma processing, therefore preferably, a material highly resistant to plasma is selected.

The above example has the configuration for reducing the shearing stress generated in the bonding layer 2 between the electrode block 1 and the sintered plate 3 because of the difference in coefficient of thermal expansion between the electrode block 1 and the sintered plate 3. Such a configuration can provide a processing apparatus that improves the yield ratio correspondingly to the increasing diameter of a sample, such as a wafer having a diameter of 450 mm.

Also, the occurrence of peeling off each other, losses and gaps of the members constituting the sample stage 101 is suppressed and the heat transfer between the sample 5 and the sample stage 101 is controlled so that it does not become non-uniform in the in-plane direction of the mounting surface of the sample 5. Consequently, a shift from a desired temperature of the sample 5 can be reduced to achieve temperature with a high accuracy, and a range for achieving the temperature can be expanded. This can allow a sample having a large area to be plasma-processed with a high accuracy.

Also, in some recent plasma processing apparatuses, after processing of the sample 5, such as etching, is completed, the sample 5 is brought out from the processing chamber 23 and plasma is formed in the processing chamber 23 so that the surface of a member in the processing chamber 23 is cleaned by interaction with the plasma. On such a cleaning, the surface of the sample stage 101 is directly exposed to the plasma, but in the above example, the member of the surface on which the sample 5 is mounted and electrostatically stuck thereto is made of dielectric material in a form of the sintered plate 3 and the Coulomb sticking system is adopted so that temporal change of the sticking force and occurrence of foreign matters are suppressed.

The sample stage proposed by the present invention for a semiconductor manufacturing apparatus is not limited to the above examples of the plasma processing apparatus, and can be diverted to other apparatuses demanding a precise, wafer temperature management, such as an ashing apparatus, a sputtering apparatus, an ion implanting apparatus, a resist applying apparatus, a plasma CVD apparatus, a flat panel display manufacturing apparatus, a solar cell manufacturing apparatus.

It should be further understood by those skilled in the art that although the foregoing description has been made on embodiments of the invention, the invention is not limited thereto and various changes and modifications may be made without departing from the spirit of the invention and the scope of the appended claims.

1. A plasma processing apparatus, comprising:
a vacuum vessel,
a processing chamber which is disposed inside of the vacuum vessel, inside of which plasma is formed,
a sample stage which is disposed below the processing chamber, on whose upper surface a sample that is a target processed by using the plasma is mounted,
a sintered plate of dielectric material which constitutes a mounting surface of the sample stage on which the sample is mounted,
a base material of metal which is bonded to the sintered plate below it with a bonding layer made of an adhesive agent intervening therebetween, and
a cooling medium flow channel which is disposed inside of the base material, through which a cooling medium flows, wherein
a thickness of the bonding layer is made thicker in a portion on a peripheral side of the sample stage than in a portion on a center side.

2. The plasma processing apparatus according to claim 1, wherein
a distance between the base material and the sintered plate is lengthened in the portion on the peripheral side, and
in the portion on the peripheral side having the lengthened distance, the adhesive agent is disposed.

3. The plasma processing apparatus according to claim 2, wherein
a distance between the base material and the sintered plate is lengthened toward a peripheral edge of the sintered plate.

4. The plasma processing apparatus according to claim 2, further comprising
at least one ring-shaped depressed portion which is separated by a step and disposed in a surface on a side where the base material is bonded to the sintered plate, the depressed portion surrounding a portion on the center side of the surface, wherein
a distance between a bottom surface of the depressed portion and the sintered plate is made longer than a distance between the sintered plate and the electrode block in the portion on the center side.

5. The plasma processing apparatus according to claim 1, further comprising
one of a first film and a second film, the first film being placed between the bonding layer and the electrode block and made of the same material as the dielectric material of the sintered plate, and the second film being placed between the bonding layer and the sintered plate and made of the same material as the metal of the electrode block.

6. The plasma processing apparatus according to claim 1, further comprising
a film of metal disposed inside of the bonding layer.

7. A plasma processing apparatus, comprising:
a vacuum vessel,
a processing chamber which is disposed inside of the vacuum vessel, inside of which plasma is formed,
a sample stage which is disposed below the processing chamber, on whose upper surface a sample that is a target processed by using the plasma is mounted,
a sintered plate of dielectric material which constitutes a mounting surface of the sample stage on which the sample is mounted,
a base material of metal which is bonded to the sintered plate below it with a bonding layer made of an adhesive agent intervening therebetween, and
a cooling medium flow channel which is disposed inside of the base material, through which a cooling medium flows, wherein
a hardness of the adhesive agent for the bonding layer is made smaller in a portion on a peripheral side of the sample stage than in a portion on a center side.

8. The plasma processing apparatus according to claim 7, wherein
a distance between the base material and the sintered plate is lengthened in the portion on the peripheral side, and
in the portion on the peripheral side having the lengthened distance, the adhesive agent is disposed.

9. The plasma processing apparatus according to claim 8, wherein
a distance between the base material and the sintered plate is lengthened toward a peripheral edge of the sintered plate.

10. The plasma processing apparatus according to claim 8, further comprising
at least one ring-shaped depressed portion which is separated by a step and disposed in a surface on a side where the base material is bonded to the sintered plate, the depressed portion surrounding a portion on the center side of the surface, wherein
a distance between a bottom surface of the depressed portion and the sintered plate is made longer than a distance between the sintered plate and the electrode block in the portion on the center side.

11. The plasma processing apparatus according to claim 7, further comprising
one of a first film and a second film, the first film being placed between the bonding layer and the electrode block and made of the same material as the dielectric material of the sintered plate, and the second film being placed between the bonding layer and the sintered plate and made of the same material as the metal of the electrode block.

12. The plasma processing apparatus according to claim 7, further comprising
a film of metal disposed inside of the bonding layer.

13. A plasma processing apparatus, comprising:
a vacuum vessel,
a processing chamber which is disposed inside of the vacuum vessel, inside of which plasma is formed,
a sample stage which is disposed below the processing chamber, on whose upper surface a sample that is a target processed by using the plasma is mounted,
a sintered plate of dielectric material which constitutes a mounting surface of the sample stage on which the sample is mounted,
a base material of metal which is bonded to the sintered plate below it with a bonding layer made of an adhesive agent intervening therebetween, and
a cooling medium flow channel which is disposed inside of the base material, through which a cooling medium flows, wherein
a shearing force of the bonding layer generated in a portion on a peripheral side of the sample stage is made smaller than that generated in a portion on a center side.

14. A fabricating method of a sample stage for a plasma processing apparatus, the plasma processing apparatus comprising:
a vacuum vessel,
a processing chamber which is disposed inside of the vacuum vessel, inside of which plasma is formed, and
a sample stage which is disposed below the processing chamber, on whose upper surface a sample that is a target processed by using the plasma is mounted, including:
a sintered plate of dielectric material which constitutes a mounting surface on which the sample is mounted,
a base material of metal which is bonded to the sintered plate below it with a bonding layer made of an adhesive agent intervening therebetween, and
a cooling medium flow channel which is disposed inside of the base material, through which a cooling medium flows, the method comprising the steps of:
placing an adhesive agent between a central portion of an upper surface of the base material and the sintered plate to connect them to each other while keeping a predetermined distance, and
introducing an adhesive agent into a depressed portion where a distance between the upper surface of the base material and the sintered plate is lengthened, the depressed portion disposed on a peripheral side of the central portion of the upper surface of the base material in a manner of surrounding the central portion, wherein
the sample stage is fabricated wherein the sintered plate and the base material are bonded to each other.

15. The fabricating method of a sample stage according to claim 14, wherein
the adhesive agent introduced into the depressed portion has a hardness lower than the adhesive agent in the central portion.
